(19) United States
(12) Patent Application Publication
(10) Pub. No.: US 2016/0131701 A1
(43) Pub. Date: May 12, 2016

(54) BATTERY TESTING SYSTEM AND METHOD

(71) Applicant: FORD GLOBAL TECHNOLOGIES, LLC, Dearborn, MI (US)

(72) Inventors: JAMES MATTHEW MARCICKI, Livonia, MI (US); THOMAS J. COUPAR, Ann Arbor, MI (US); PHILIPPE S. RAIRIGH, Dearborn, MI (US)

(21) Appl. No.: 14/535,586

(22) Filed: Nov. 7, 2014

(51) Int. Cl. G01R 31/28; G01R 31/36

(52) U.S. Cl. CPC G01R 31/2874; G01R 31/3627; G01R 31/3662

(57) ABSTRACT

A battery testing method according to an exemplary aspect of the present disclosure includes, among other things, controlling a temperature of an environmental chamber that houses at least one battery cell during a test cycle to maintain a relatively constant temperature of the at least one battery cell throughout the test cycle.

### TECHNICAL FIELD

This disclosure relates to a battery testing system and method for testing battery cells of an electrified vehicle. The battery testing system includes the necessary hardware and software for maintaining a nearly constant battery temperature during a test cycle by dynamically controlling a temperature of an environmental testing chamber.

### BACKGROUND

The need to reduce automotive fuel consumption and emissions is well known. Therefore, vehicles are being developed that reduce or completely eliminate reliance on internal combustion engines. Electrified vehicles are one type of vehicle being developed for this purpose. In general, electrified vehicles differ from conventional motor vehicles because they are selectively driven by one or more battery powered electric machines. Conventional motor vehicles, by contrast, rely exclusively on the internal combustion engine to drive the vehicle.

Electrified vehicle batteries may employ battery cells, such as lithium-ion battery cells. These battery cells are typically validated by extensive testing. During such testing, a battery cell is charged and discharged to measure characteristics used to determine the cell's performance and usable life.

### SUMMARY

A battery testing method according to an exemplary aspect of the present disclosure includes, among other things, controlling a temperature of an environmental chamber that houses at least one battery cell during a test cycle to maintain a relatively constant temperature of the at least one battery cell throughout the test cycle.

In a further non-limiting embodiment of the foregoing method, the method includes initiating the controlling step when the at least one battery cell begins passing a current.

In a further non-limiting embodiment of either of the foregoing methods, the method includes measuring a current of the at least one battery cell and communicating a magnitude of the current to a computing device.

In a further non-limiting embodiment of any of the foregoing methods, the method includes approximating an amount of heat generated by the at least one battery cell based on the current and a resistance value associated with the at least one battery cell.

In a further non-limiting embodiment of any of the foregoing methods, the method includes measuring the temperature of the at least one battery cell and communicating the measurement of the temperature of the at least one battery cell to the computing device.

In a further non-limiting embodiment of any of the foregoing methods, the method includes comparing the measurement of the temperature of the at least one battery cell to a desired temperature set point of the at least one battery cell to compute an error signal and then calculating a desired temperature of an interior of the environmental chamber.

In a further non-limiting embodiment of any of the foregoing methods, the calculating step utilizes the following equation:

$${T}_{ch , 0} = {T}_{0} - {K}_{p} e - {K}_{I} {\int }_{0}^{t} e \cdot d t - {K}_{ff} {Q}_{b}$$

where T_{ch,0} is the desired temperature of the interior of the environmental chamber, T₀ is the desired battery temperature set point, K is a gain factor, e is an error signal and Q_{b} is the heat generated by the at least one battery cell.

In a further non-limiting embodiment of any of the foregoing methods, the method includes communicating a command signal from the computing device to a controller of the environmental chamber, the command signal representative of the desired temperature of the interior of the environmental chamber.

In a further non-limiting embodiment of any of the foregoing methods, the method includes comparing the desired temperature to an actual temperature of the interior.

In a further non-limiting embodiment of any of the foregoing methods, the method includes regulating the temperature of the environmental chamber to the desired temperature.

In a further non-limiting embodiment of any of the foregoing methods, the method includes commanding a climate control unit of the environmental chamber in a heating mode to heat the environmental chamber if the actual temperature is below the desired temperature or commanding the climate control unit in a cooling mode if the actual temperature is above the desired temperature.

In a further non-limiting embodiment of any of the foregoing methods, the method includes identifying an increase in an internal resistance value of the at least one battery cell and updating a calculation of an amount of heat generated by the at least one battery cell based on the increased internal resistance value.

In a further non-limiting embodiment of any of the foregoing methods, the method includes measuring an initial voltage of the at least one battery cell, after an elapsed time, measuring a current and a second voltage of the at least one battery cell and calculating an updated internal resistance value associated with the at least one battery cell based on the initial voltage, the second voltage and the current.

In a further non-limiting embodiment of any of the foregoing methods, the controlling step includes selectively cooling or heating an interior of the environmental chamber during the test cycle.

In a further non-limiting embodiment of any of the foregoing methods, the controlling step includes continuously adjusting the temperature of the environmental chamber based on an amount of heat generated by the at least one battery cell during the test cycle.

A battery testing system according to another exemplary aspect of the present disclosure includes, among other things, an environmental chamber housing a battery cell and a controller configured to dynamically control a temperature of the environmental chamber based on an amount of heat generated by the battery cell during a test cycle.

In a further non-limiting embodiment of the foregoing system, a current sensor is configured to measure a current passed by the battery cell and a temperature sensor configured to measure a temperature of the battery cell.

In a further non-limiting embodiment of either of the foregoing systems, a computing device is in communication with the controller and configured to communicate a command signal representative of a desired temperature of the environmental chamber to the controller.

In a further non-limiting embodiment of any of the foregoing systems, the controller is configured to modulate a climate control unit of the environmental chamber to alter the temperature of the environmental chamber during the test cycle.

In a further non-limiting embodiment of any of the foregoing systems, the controller is configured to continuously adjust the temperature of the environmental chamber to maintain a relatively constant temperature of the battery cell throughout the test cycle.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

The various features and advantages of this disclosure will become apparent to those skilled in the art from the following detailed description. The drawings that accompany the detailed description can be briefly described as follows.

### BRIEF DESCRIPTION OF THE DRAWINGS

FIG. 1 schematically illustrates a powertrain of an electrified vehicle.

FIG. 2 schematically illustrates a battery testing system.

FIG. 3 schematically illustrates a battery testing method for dynamically controlling the temperature of an environmental chamber of a battery testing system.

FIG. 4 schematically illustrates a method for identifying an increase in battery cell internal resistance.

FIG. 5 is a plot of battery cell and environmental chamber temperature responses during a test cycle of a battery testing system.

### DETAILED DESCRIPTION

This disclosure relates to a battery testing system and method for measuring the performance and usable life of battery cells. The battery testing system includes, among other features, an environmental chamber and a controller. A battery cell is positioned within the environmental chamber and subsequently charged and discharged during a test cycle. The controller is configured to dynamically control a temperature of the environmental chamber to maintain a nearly constant battery cell temperature during the test cycle. The temperature of the environmental chamber may be continuously adjusted throughout the test cycle based on an amount of heat generated by the battery cell being tested. These and other features are discussed in greater detail in the paragraphs that follow.

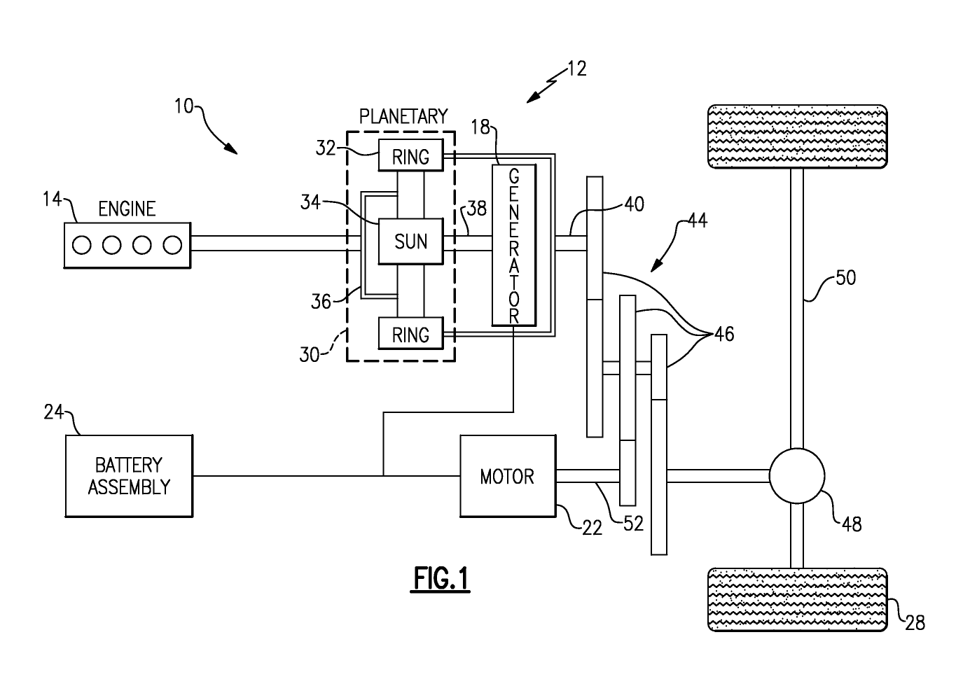

FIG. 1 schematically illustrates a powertrain 10 for an electrified vehicle 12. Although depicted as a HEV, it should be understood that the concepts described herein are not limited to HEV's and could extend to other electrified vehicles, including, but not limited to, plug-in hybrid electric vehicles (PHEV's) and battery electric vehicles (BEV's).

In one embodiment, the powertrain 10 is a power-split powertrain system that employs a first drive system and a second drive system. The first drive system includes a combination of an engine 14 and a generator 18 (i.e., a first electric machine). The second drive system includes at least a motor 22 (i.e., a second electric machine), the generator 18, and a battery assembly 24. In this example, the second drive system is considered an electric drive system of the powertrain 10. The first and second drive systems generate torque to drive one or more sets of vehicle drive wheels 28 of the electrified vehicle 12.

The engine 14, such as an internal combustion engine, and the generator 18 may be connected through a power transfer unit 30, such as a planetary gear set. Of course, other types of power transfer units, including other gear sets and transmissions, may be used to connect the engine 14 to the generator 18. In one non-limiting embodiment, the power transfer unit 30 is a planetary gear set that includes a ring gear 32, a sun gear 34, and a carrier assembly 36.

The generator 18 can be driven by the engine 14 through the power transfer unit 30 to convert kinetic energy to electrical energy. The generator 18 can alternatively function as a motor to convert electrical energy into kinetic energy, thereby outputting torque to a shaft 38 connected to the power transfer unit 30. Because the generator 18 is operatively connected to the engine 14, the speed of the engine 14 can be controlled by the generator 18.

The ring gear 32 of the power transfer unit 30 may be connected to a shaft 40, which is connected to vehicle drive wheels 28 through a second power transfer unit 44. The second power transfer unit 44 may include a gear set having a plurality of gears 46. Other power transfer units may also be suitable. The gears 46 transfer torque from the engine 14 to a differential 48 to ultimately provide traction to the vehicle drive wheels 28. The differential 48 may include a plurality of gears that enable the transfer of torque to the vehicle drive wheels 28. In one embodiment, the second power transfer unit 44 is mechanically coupled to an axle 50 through the differential 48 to distribute torque to the vehicle drive wheels 28.

The motor 22 can also be employed to drive the vehicle drive wheels 28 by outputting torque to a shaft 52 that is also connected to the second power transfer unit 44. In one embodiment, the motor 22 and the generator 18 cooperate as part of a regenerative braking system in which both the motor 22 and the generator 18 can be employed as generators. The motor 22 can output electrical power to the battery assembly 24.

The battery assembly 24 is an example type of electrified vehicle battery assembly. The battery assembly 24 may include a high voltage battery that includes a plurality of battery cells capable of outputting electrical power to operate the motor 22 and the generator 18. Other types of energy storage devices and/or output devices can also be used to electrically power the electrified vehicle 12. The battery cells of the battery assembly 24 may undergo validation testing prior to use within the electrified vehicle 12. Exemplary battery testing systems and methods for performing validation testing are discussed in greater detail below.

In one non-limiting embodiment, the electrified vehicle 12 has two basic operating modes. The electrified vehicle 12 may operate in an Electric Vehicle (EV) mode where the motor 22 is used (generally without assistance from the engine 14) for vehicle propulsion, thereby depleting the battery assembly 24 state of charge up to its maximum allowable discharging rate under certain driving patterns/cycles. The EV mode is an example of a charge depleting mode of operation for the electrified vehicle 12. During EV mode, the state of charge of the battery assembly 24 may increase in some circumstances, for example due to a period of regenerative braking. The engine 14 is generally OFF under a default EV mode but could be operated as necessary based on a vehicle system state or as permitted by the operator.

The electrified vehicle 12 may additionally be operated in a Hybrid (HEV) mode in which the engine 14 and the motor 22 are both used for vehicle propulsion. The HEV mode is an example of a charge sustaining mode of operation for the electrified vehicle 12. During the HEV mode, the electrified vehicle 12 may reduce or increase the motor 22 propulsion usage in order to maintain the state of charge of the battery assembly 24 constant or approximately constant. The electrified vehicle 12 may be operated in other operating modes in addition to the EV and HEV modes within the scope of this disclosure.

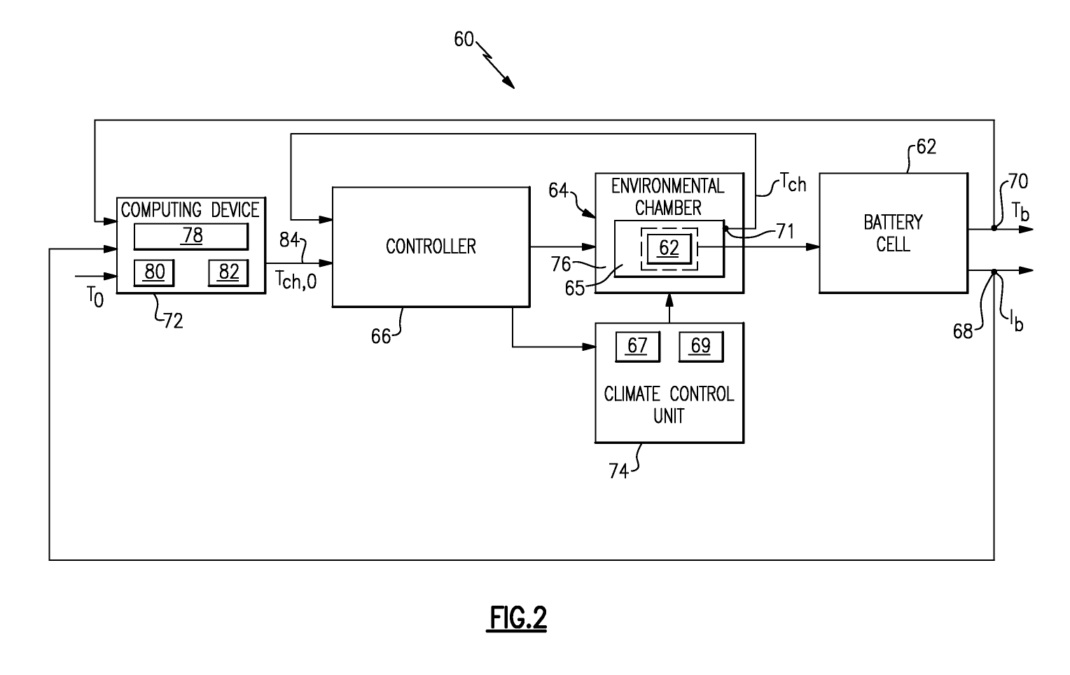

FIG. 2 illustrates a battery testing system 60 for testing and/or evaluating one or more battery cells 62. For example, the battery testing system 60 may be employed to evaluate the performance and usable life of a battery cell 62. In one non-limiting embodiment, as discussed in greater detail below, the battery testing system 60 is adapted to dynamically control a temperature of an environmental testing chamber during a testing cycle to more accurately predict performance and usable life of the battery cell 62. Dynamically controlling the temperature of the environmental chamber maintains a nearly constant battery cell temperature during the testing cycle.

In the illustrated embodiment, a single battery cell 62 is being tested by the battery testing system 60. However, the battery testing system 60 could be employed to simultaneously test multiple battery cells. The battery cell 62 could be part of a high voltage battery assembly, such as the battery assembly 24 of the electrified vehicle 12 of FIG. 1. In one non-limiting embodiment, the battery cells 62 are lithium-ion battery cells. However, the battery cells 62 could be any type of cell, including but not limited to, nickel metal hydride cells, lead acid cells, etc. In other words, the battery testing system 60 could be utilized to evaluate the performance characteristics of any type of battery cell within the scope of this disclosure.

The battery testing system 60 includes the necessary hardware and software (i.e., algorithms, etc.) for evaluating and testing the battery cell 62. In one embodiment, the battery testing system 60 includes an environmental chamber 64, a controller 66, a current sensor 68, temperature sensors 70, 71, and a computing device 72.

The environmental chamber 64 includes a housing 76 that surrounds an interior 65. One or more battery cells 62 may be positioned within the interior 65 during a testing cycle. The current sensor 68 measures the current directed to and from the battery cell 62 during charging and discharging operations and may be mounted near the battery cell 62 (but outside of the environmental chamber 64). The temperature sensor 70 senses a temperature of the battery cell 62 and may be mounted on the battery cell 62. A temperature T_{b} monitored by the temperature sensor 70 and a current I_{b} monitored by the current sensor 68 may be periodically communicated to the computing device 72 for further processing.

The environmental chamber 64 may additionally include a climate control unit 74 for regulating the temperature of the interior 65 of the environmental chamber 64 to a commanded value during a test cycle. In one non-limiting embodiment, the climate control unit 74 includes a compressor 67 with a cooling coil for selectively cooling the interior 65 and an electric heater 69 for selectively heating the interior 65. The climate control unit 74 may embody other configurations within the scope of this disclosure.

A temperature sensor 71 may monitor an actual temperature T_{ch} of the interior 65 of the environmental chamber 64. The temperature sensor 71, which may be a thermocouple, may be mounted within the interior 65 or to any other portion of the environmental chamber 64. The temperature sensor 71 may communicate the actual temperature T_{ch} to the controller 66 for comparison to a desired temperature T_{ch,0}, which is calculated by the computing device 72.

The controller 66 is in communication with the environmental chamber 64, including the climate control unit 74, or may be part of the climate control unit 74. In one embodiment, the controller 66 may command the climate control unit 74 to either heat or cool the interior 65 of the environmental chamber 64 in order to dynamically control the temperature of the interior 65 during a test cycle. Control of the climate control unit 74 may be based on a comparison of the actual temperature T_{ch} to the desired temperature T_{ch,0}. For example, if the actual temperature T_{ch} is below the desired temperature T_{ch,0}, the controller 66 may command the climate control unit 74 in a heating mode to heat the interior 65, whereas if the actual temperature T_{ch} is above the desired temperature T_{ch,0}, the controller 66 may command the climate control unit 74 in a cooling mode to cool the interior 65.

The computing device 72 may include a data acquisition system 78 that is capable of accepting signals from the current sensor 68 and the temperature sensor 70. In one non-limiting embodiment, the computing device 72 is a personal computer and the data acquisition system 78 includes LabVIEW software. Additional non-limiting examples of suitable data acquisition systems include Arduino, Raspberry PI, or Basic Stamp. The data acquisition system 78 is capable of executing low-level coding language commands to compute a desired output signal. In another embodiment, the computing device 72 may act as the data acquisition system 78 and the controller 66.

In one embodiment, the computing device 72 may include a central processing unit 80 and non-transitory memory 82 for performing mathematical operations (using programmed algorithms, etc.) based on input signals received from the current sensor 68 and the temperature sensor 70 in order to calculate a desired temperature T_{ch,0} of the interior 65 of the environmental chamber 64. The computing device 72 is also adapted to communicate a command signal 84 representative of the desired temperature T_{ch,0} to the controller 66 of the environmental chamber 64. The controller 66 may then command the climate control unit 74 into either the heating mode or the cooling mode in response to receiving the command signal 84.

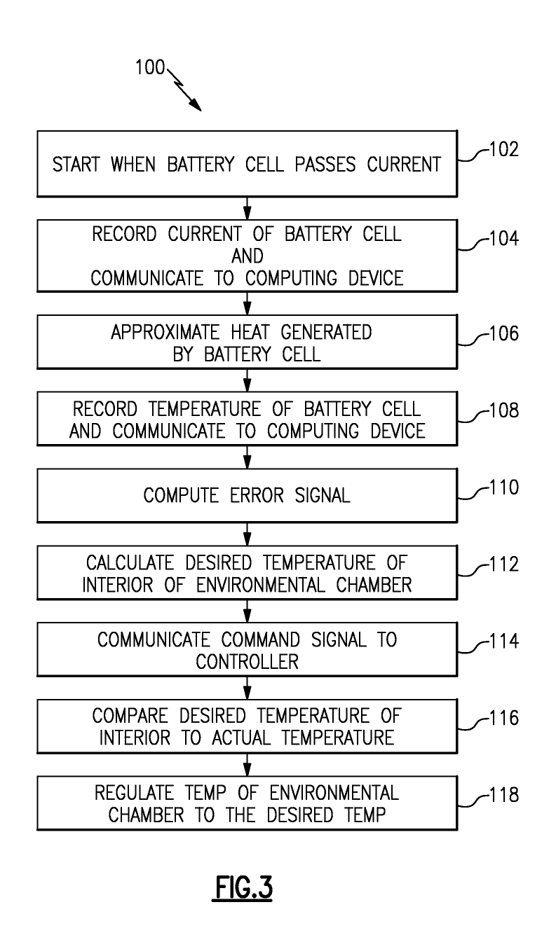

FIG. 3, with continued reference to FIGS. 1 and 2, schematically illustrates a battery testing strategy 100 for testing and evaluating one or more battery cells 62 using the battery testing system 60. The battery testing strategy 100 may be executed during a battery test cycle to maintain a nearly constant temperature of the battery cell(s) 62 by dynamically regulating the temperature of the environmental chamber 64 throughout the test cycle. In one embodiment, the computing device 72 of the battery testing system 60 may be programmed with one or more algorithms adapted to execute the battery testing strategy 100. The battery testing strategy 100 may be stored as executable instructions in the non-transitory memory 82 of the computing device 72.

As shown in FIG. 3, the battery testing strategy 100 begins at block 102 when the battery cell 62 undergoing testing starts to pass a current. The battery cell 62 may be subjected to charging and discharging operations in a known manner in order to cause the battery cell 62 to pass a current.

At step block 104, the current I_{b} is recorded by the current sensor 68 and is communicated to the computing device 72. Next, at step block 106, the computing device 72 may approximate the heat Q_{b} generated by the battery cell 62. In one embodiment, the heat Q_{b} generated by the battery cell 62 is a product of the current I_{b} and a resistance value R of the battery cell 62. The heat Q_{b} may be calculated using the following equation (1):

Q_{b}=(I_{b})²×R (1)

where:
Q_{b} is the heat generated by the battery cell;
I_{b} is the current magnitude of the battery cell; and
R is the cell resistance value (which may be a function of battery cell temperature, state of charge, state of health, etc.).

As the current flows, the battery cell 62 generates heat and its temperature T_{b} may begin to rise. This temperature change is recorded by the temperature sensor 70 and is transmitted to the computing device 72 at step block 108. The computing device 72 compares the measured battery temperature T_{b} with a desired temperature set point T₀, which may be stored in the non-transitory memory 82, to compute an error signal e at step block 110. This calculation is expressed in equation (2):

e=T_{b}−T₀ (2)

The desired temperature T_{ch,0} of the interior 65 of the environmental chamber 64 is calculated at step block 112. This calculation is expressed by equation (3), shown below:

$${T}_{ch , 0} = {T}_{0} - {K}_{p} e - {K}_{I} {\int }_{0}^{t} e \cdot d t - {K}_{ff} {Q}_{b} \qquad ( 3 )$$

where:
T_{ch,0} is the desired temperature of the interior of the environmental chamber;
T₀ is the desired battery temperature set point;
K is a gain factor;
e is an error signal; and
Q_{b} is the heat generated by the battery cell.

As is evident from equation (3), the computing device 72 may integrate the error signal e with respect to time and then apply gain factors K to the heat generated Q_{b}, the error signal e, and the time integrated error signal e. These gain modified signals are summed to calculate a linear combination of the three signals. This linear combination is subtracted from the desired temperature set point T₀ to compute the desired temperature T_{ch,0} of the interior 65 of the environmental chamber 64.

Next, at step block 114, the command signal 84 representative of the desired temperature T_{ch,0} is communicated from the computing device 72 to the controller 66 of the environmental chamber 64. The controller 66 compares the desired temperature T_{ch,0} to the actual temperature T_{ch} (monitored by the temperature sensor 71) at step block 116.

Finally, at step block 118, the controller 66 regulates the temperature of the environmental chamber 64 to the desired temperature T_{ch,0}. This step may include modulating the climate control unit 74 of the environmental chamber 64 to either a heating mode or a cooling mode. For example, the controller 66 may command the climate control unit 74 in a heating mode to heat the interior 65 if the actual temperature T_{ch} is below the desired temperature T_{ch,0} or the controller 66 may command the climate control unit 74 in a cooling mode if the actual temperature T_{ch} is above the desired temperature T_{ch,0}.

Step blocks 102 through 118 and equations (1), (2) and (3) described above are representative of one type of control strategy that may be executed by the battery testing system 60. It should be understood that other types of algorithms could alternatively or additionally be embedded in the computing device 72 and/or the controller 66, including proportional, proportional-integral (PI), or other mathematical operations performed on the error signal e and the battery heat generation Q_{b}. By way of non-limiting examples, this could include integration of the current I_{b} to calculate the instantaneous battery state-of-charge, a look-up table based on a heating parameter that is a function of state-of-charge, the calculation of an average of several temperature sensors, or the calculation of an internal battery temperature using external temperature sensors, and using these signals to derive a desired temperature T_{ch,0} of the environmental chamber 64.

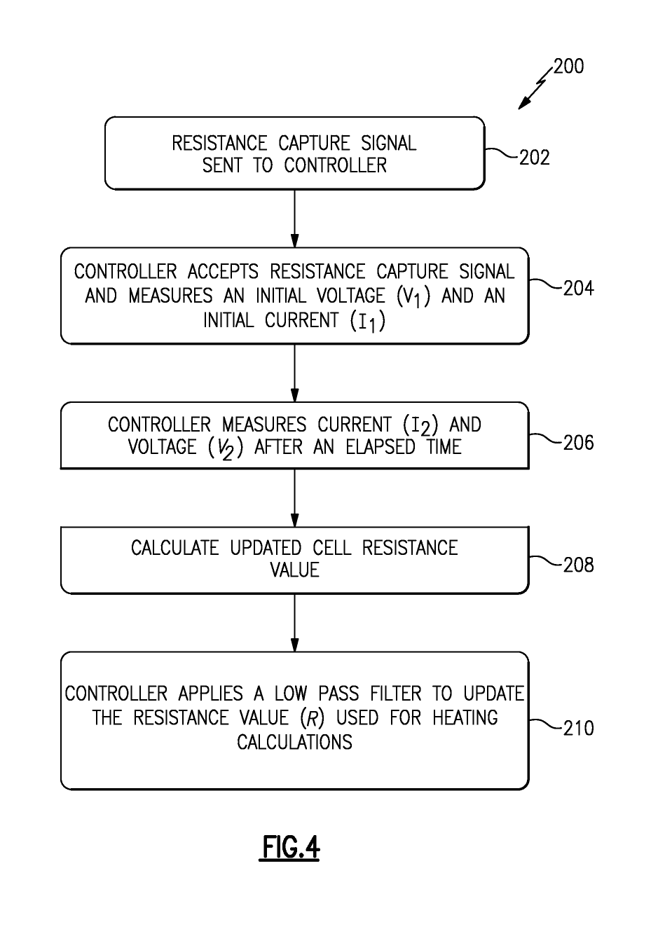

Over time and as a result of passing current, the resistance R of the battery cell 62 may increase, causing the heat Q_{b} produced by the battery cell 62 to also increase. The computing device 72 may therefore include an adaptive algorithm to identify increases in battery internal resistance and modify its control parameters accordingly to maintain a constant battery set point temperature despite the increased heat of the battery cell 62. A flow chart of an exemplary battery testing strategy 200 for this purpose is illustrated in FIG. 4. In one embodiment, the battery testing strategy 200 is performed in conjunction with the battery testing strategy 100 of FIG. 3.

At a pre-designated point during a test cycle, a resistance capture signal may be sent to the computing device 72 at block 202 to begin the resistance capture process. The resistance capture signal may be generated in a variety of ways. In one non-limiting embodiment, a digital input/output port of the battery testing system 60 may be commanded to capture the resistance value R during the test cycle.

At step block 204, the computing device 72 accepts the resistance capture signal and measures an initial voltage V₁ and initial current I₁ of the battery cell 62. After an elapsed amount of time, the computing device 72 measures a current I₂ and a voltage V₂ of the battery cell 62 at step block 206. In one non-limiting embodiment, the elapsed amount of time is one second. The value of I₂ is ideally a step change from I₁. Next, at step block 208, the computing device 72 calculates an updated cell resistance value R_{new}. This calculation may be expressed by equation (4), shown below:

R_{new}(k)=(V₂−V₁)/(I₂−I₁) (4)

Finally, the cell resistance update value is low pass filtered and used to continuously update the heating calculation performed by computing device 72 at block 210. This calculation may be expressed by the following equation (5):

R(k)=αR_{new}(k)+(1−α)R(k−1) (5)

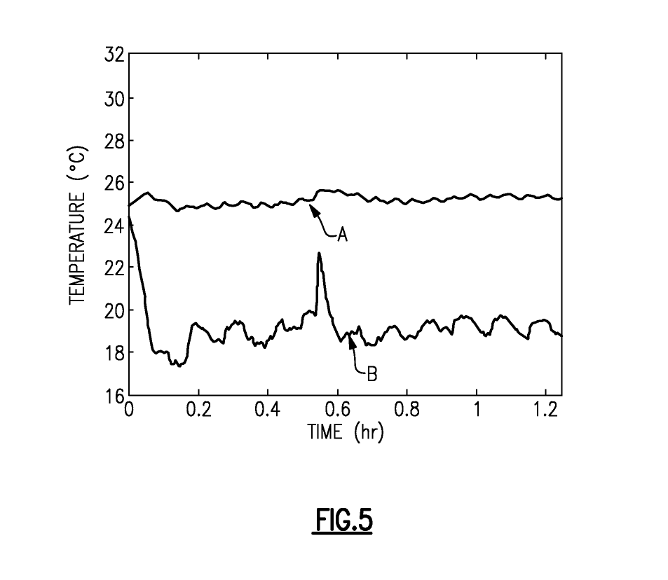

FIG. 5 schematically illustrates a plot of battery cell temperature versus time during a test cycle of a battery cell 62 using the battery testing system 60 described above. Plot A illustrates the temperature of the battery cell 62 during the test cycle, whereas plot B illustrates the temperature of the environmental chamber 64 during the test cycle. As is evident from these plots, the temperature of the battery cell 62 is maintained relatively constant (i.e., ±0.5° C.) by dynamically controlling (i.e., increasing or decreasing) the temperature of the environmental chamber 64 throughout the test cycle.

Although the different non-limiting embodiments are illustrated as having specific components or steps, the embodiments of this disclosure are not limited to those particular combinations. It is possible to use some of the components or features from any of the non-limiting embodiments in combination with features or components from any of the other non-limiting embodiments.

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

The foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

What is claimed is:

1. A battery testing method, comprising:
controlling a temperature of an environmental chamber that houses at least one battery cell during a test cycle to maintain a relatively constant temperature of the at least one battery cell throughout the test cycle.

2. The method as recited in claim 1, comprising
initiating the controlling step when the at least one battery cell begins passing a current.

3. The method as recited in claim 1, comprising:
measuring a current of the at least one battery cell; and
communicating a magnitude of the current to a computing device.

4. The method as recited in claim 3, comprising:
approximating an amount of heat generated by the at least one battery cell based on the current and a resistance value associated with the at least one battery cell.

5. The method as recited in claim 4, comprising:
measuring the temperature of the at least one battery cell; and
communicating the measurement of the temperature of the at least one battery cell to the computing device.

6. The method as recited in claim 5, comprising:
comparing the measurement of the temperature of the at least one battery cell to a desired temperature set point of the at least one battery cell to compute an error signal; and then
calculating a desired temperature of an interior of the environmental chamber.

7. The method as recited in claim 6, wherein the calculating step utilizes the following equation:
$${T}_{ch , 0} = {T}_{0} - {K}_{p} e - {K}_{I} {\int }_{0}^{t} e \cdot d t - {K}_{ff} {Q}_{b}$$
where:
T_{ch,0} is the desired temperature of the interior of the environmental chamber;
T₀ is the desired battery temperature set point;
K is a gain factor;
e is an error signal; and
Q_{b} is the heat generated by the at least one battery cell.

8. The method as recited in claim 6, comprising communicating a command signal from the computing device to a controller of the environmental chamber, the command signal representative of the desired temperature of the interior of the environmental chamber.

9. The method as recited in claim 8, comprising comparing the desired temperature to an actual temperature of the interior.

10. The method as recited in claim 9, comprising regulating the temperature of the environmental chamber to the desired temperature.

11. The method as recited in claim 8, comprising:
commanding a climate control unit of the environmental chamber in a heating mode to heat the environmental chamber if the actual temperature is below the desired temperature; or
commanding the climate control unit in a cooling mode if the actual temperature is above the desired temperature.

12. The method as recited in claim 1, comprising:
identifying an increase in an internal resistance value of the at least one battery cell; and
updating a calculation of an amount of heat generated by the at least one battery cell based on the increased internal resistance value.

13. The method as recited in claim 1, comprising:
measuring an initial voltage of the at least one battery cell;
after an elapsed time, measuring a current and a second voltage of the at least one battery cell; and
calculating an updated internal resistance value associated with the at least one battery cell based on the initial voltage, the second voltage and the current.

14. The method as recited in claim 1, wherein the controlling step includes selectively cooling or heating an interior of the environmental chamber during the test cycle.

15. The method as recited in claim 1, wherein the controlling step includes continuously adjusting the temperature of the environmental chamber based on an amount of heat generated by the at least one battery cell during the test cycle.

16. A battery testing system, comprising:
an environmental chamber housing a battery cell; and
a controller configured to dynamically control a temperature of said environmental chamber based on an amount of heat generated by said battery cell during a test cycle.

17. The system as recited in claim 16, comprising a current sensor configured to measure a current passed by said battery cell and a temperature sensor configured to measure a temperature of said battery cell.

18. The system as recited in claim 16, comprising a computing device in communication with said controller and configured to communicate a command signal representative of a desired temperature of said environmental chamber to said controller.

19. The system as recited in claim 16, wherein said controller is configured to modulate a climate control unit of said environmental chamber to alter said temperature of said environmental chamber during said test cycle.

20. The system as recited in claim 16, wherein said controller is configured to continuously adjust the temperature of said environmental chamber to maintain a relatively constant temperature of said battery cell throughout said test cycle.
